(19) United States
(12) Patent Application Publication
(10) Pub. No.: US 2017/0309611 A1
(43) Pub. Date: Oct. 26, 2017

(54) FORMING A SELF-ALIGNED SINGLE DIFFUSION BREAK (SDB) ISOLATION STRUCTURE IN A GATE REGION OF A DIODE FOR REDUCED CAPACITANCE, RESISTANCE, AND/OR AREA

(71) Applicant: QUALCOMM Incorporated, San Diego, CA (US)

(72) Inventors: Yanxiang Liu, San Diego, CA (US); Haining Yang, San Diego, CA (US); Junjing Bao, San Diego, CA (US)

(21) Appl. No.: 15/133,377

(22) Filed: Apr. 20, 2016

(51) Int. Cl. H01L 27/02; H01L 29/06; H01L 29/66

(52) U.S. Cl. CPC H01L 27/0255; H01L 29/66545; H01L 29/0646; H01L 29/0649

(57) ABSTRACT

Aspects for forming a self-aligned single diffusion break (SDB) isolation structure in a gate region of a diode for reduced capacitance, resistance, and/or area are disclosed. In one aspect, a diode is provided that includes a semiconductor substrate having a well region. P-doped and N-doped diffusion regions are formed in the well region of the semiconductor substrate. A self-aligned SDB isolation structure is formed in and self-aligned with a gate region between the P-doped and N-doped diffusion regions that electrically isolates such regions. The self-aligned SDB isolation structure reduces the parasitic capacitance of the diode compared to diodes having conductive gate structures in the gate region. The self-aligned SDB isolation structure has a width that reduces the length of a discharge path compared to conventional diodes, which reduces on-state resistance of the diode.

### BACKGROUND

### I. Field of the Disclosure

The technology of the disclosure relates generally to diodes, and more particularly to isolation structures provided in the diode to electrically isolate the anode and cathode of the diode.

### II. Background

Electro-static discharge (ESD) is a common cause of reliability problems in integrated circuits (ICs). ESD is a transient surge in voltage (negative or positive) that can induce a large current in a circuit. To protect circuits against damage from ESD surges, protection schemes attempt to provide a discharge path for both positive and negative ESD surges. Conventional diodes can be employed in ESD protection circuits to clamp the voltage of positive and negative ESD surges to shunt and prevent excessive current from being applied to a protected circuit.

For example, FIG. 1 illustrates an exemplary ESD protection circuit 100 configured to provide ESD protection to a protected circuit 102. The ESD protection circuit 100 is coupled between a voltage rail 104 and a ground rail 106 so as to protect the protected circuit 102 from both positive and negative ESD surges. In this manner, the ESD protection circuit 100 includes a positive ESD surge diode 108 and a negative ESD surge diode 110. The positive ESD surge diode 108 clamps positive voltage on a signal pin 112. In particular, in response to positive ESD surges on the signal pin 112, the positive ESD surge diode 108 is forward-biased and clamps voltage on the signal pin 112 to one diode drop above the voltage rail 104. Energy from such a positive ESD surge is conducted through the positive ESD surge diode 108 in a forward-biased mode and dispersed onto the voltage rail 104. In contrast, the negative ESD surge diode 110 clamps negative voltage on the signal pin 112. More specifically, in response to negative ESD surges on the signal pin 112, the negative ESD surge diode 110 is forward-biased so as to provide a low-impedance path relative to the protected circuit 102. Energy from the negative ESD surge dissipates onto the ground rail 106.

While the ESD protection circuit 100 in FIG. 1 provides protection against ESD surges, various design parameters of the ESD protection circuit 100 can negatively impact corresponding ICs. For example, capacitance corresponding to the positive and negative ESD surge diodes 108, 110 contributes to a resistor-capacitor (RC) delay of the protection circuit 100. As such capacitance increases, so too does the RC delay, which reduces the frequency at which the protected circuit 102 can operate. Higher capacitance also increases the impedance of the protected circuit 102. Increased impedance negatively affects input matching, and thus degrades the return/loss of signals input or output from the protected circuit 102 at certain frequencies. Additionally, current density of the positive and negative ESD surge diodes 108, 110 partly determines how quickly the ESD protection circuit 100 can discharge ESD surges. For example, a higher current density enables a faster discharge of ESD surges, which improves performance of the ESD protection circuit 100. However, increasing current density, which can be achieved by reducing on-state resistance or increasing area, for example, can increase manufacturing costs.

### SUMMARY OF THE DISCLOSURE

Aspects disclosed herein include forming a self-aligned single diffusion break (SDB) isolation structure in a gate region of a diode for reduced capacitance, resistance, and/or area. In one aspect, a diode is provided that includes a semiconductor substrate having a well region, and P-type material doped (P-doped) and N-type material doped (N-doped) diffusion regions formed in the well region of the semiconductor substrate. A self-aligned SDB isolation structure is formed in and self-aligned with a gate region between the P-doped and N-doped diffusion regions. The self-aligned SDB isolation structure electrically isolates the P-doped and N-doped diffusion regions such that parasitic capacitance between the P-doped and N-doped diffusion regions and the self-aligned SDB isolation structure in the gate region is reduced or avoided. Forming the self-aligned SDB isolation structure in the gate region reduces the parasitic capacitance of the diode as compared to diodes that include conductive gate structures in the gate region. Additionally, having the self-aligned SDB isolation structure self-aligned with the gate region of the diode allows the self-aligned SDB isolation structure to be formed with a width corresponding to a width of the gate region to reduce the length of a discharge path, and thus the area, of the diode as compared to conventional diodes. A shorter discharge path reduces an on-state resistance of the diode, which increases current density. Further, as another example, the self-aligned SDB isolation structure can be formed without new fabrication masks in addition to masks used in conventional SDB processes, such that the diode can achieve a reduced capacitance, resistance, and/or area without increased manufacturing costs.

In this regard in one aspect, a diode is provided. The diode comprises a semiconductor substrate comprising a well region. The diode further comprises a P-type material doped (P-doped) diffusion region formed in the well region, and an N-type material doped (N-doped) diffusion region formed in the well region. The diode further comprises a gate region disposed between the P-doped diffusion region and the N-doped diffusion region. The diode further comprises a self-aligned SDB isolation structure formed in the gate region and self-aligned with the gate region. The self-aligned SDB isolation structure provides electrical isolation between the P-doped diffusion region and the N-doped diffusion region.

In another aspect, a method for manufacturing a diode is provided. The method comprises providing a semiconductor structure comprising a well region, a P-doped diffusion region formed in the well region, an N-doped diffusion region formed in the well region, and a gate region disposed between the P-doped diffusion region and the N-doped diffusion region. The method further comprises forming a self-aligned SDB isolation structure in the gate region that is self-aligned with the gate region. The self-aligned SDB isolation structure provides electrical isolation between the P-doped diffusion region and the N-doped diffusion region.

In another aspect, an electro-static discharge (ESD) protection circuit is provided. The ESD protection circuit comprises a signal pin configured to convey a voltage signal to a protected circuit. The ESD protection circuit further comprises a positive surge diode coupled to the signal pin and a voltage rail. The positive surge diode comprises a semiconductor substrate comprising a well region. The positive surge diode further comprises a P-doped diffusion region formed in the well region, and an N-doped diffusion region formed in the well region. The positive surge diode further comprises a gate region disposed between the P-doped diffusion region and the N-doped diffusion region. The positive surge diode further comprises a self-aligned SDB isolation structure formed in the gate region and self-aligned with the gate region. The self-aligned SDB isolation structure provides electrical isolation between the P-doped diffusion region and the N-doped diffusion region. The ESD protection circuit further comprises a negative surge diode coupled to the signal pin and a ground rail. The negative surge diode comprises the semiconductor substrate. The negative surge diode further comprises a P-doped diffusion region formed in the well region, and an N-doped diffusion region formed in the well region. The negative surge diode further comprises a gate region disposed between the P-doped diffusion region and the N-doped diffusion region. The negative surge diode further comprises a self-aligned SDB isolation structure formed in the gate region and self-aligned with the gate region. The self-aligned SDB isolation structure provides electrical isolation between the P-doped diffusion region and the N-doped diffusion region.

In another aspect, a diode is provided. The diode comprises a means for providing a semiconductor substrate comprising a well region. The diode further comprises a means for providing a P-doped diffusion region formed in the well region. The diode further comprises a means for providing an N-doped diffusion region formed in the well region. The diode further comprises a means for disposing a gate region between the P-doped diffusion region and the N-doped diffusion region. The diode further comprises a means for forming a self-aligned SDB isolation structure in the gate region and self-aligned with the gate region. The self-aligned SDB isolation structure provides electrical isolation between the P-doped diffusion region and the N-doped diffusion region.

### BRIEF DESCRIPTION OF THE FIGURES

FIG. 1 is a diagram of an exemplary electro-static discharge (ESD) protection circuit configured to prevent ESD surges from damaging a protected circuit;

FIG. 2 is a cross-sectional diagram of an exemplary conventional diode having a shallow trench isolation (STI) structure separating diffusion regions corresponding to an anode and a cathode;

FIG. 3 is a cross-sectional diagram of an exemplary diode having a self-aligned single diffusion break (SDB) isolation structure separating diffusion regions corresponding to an anode and a cathode to reduce parasitic capacitance, on-state resistance, and/or area of the diode;

FIGS. 4A-4B illustrate a flowchart illustrating an exemplary process of fabricating the diode having the self-aligned SDB isolation structure in FIG. 3;

FIGS. 5A-5L are cross-sectional diagrams illustrating the diode in FIG. 3 at different fabrication steps in the process of fabrication in FIG. 4;

FIG. 6A illustrates a circuit diagram of an exemplary ESD protection circuit employing a positive surge diode and a negative surge diode, each diode having a self-aligned single diffusion break isolation structure;

FIG. 6B illustrates a cross-sectional diagram of the positive and negative surge diodes in the ESD protection circuit in FIG. 6A; and

FIG. 7 is a block diagram of an exemplary processor-based system that can include components employing the diode of FIG. 3 and/or the ESD protection circuit of FIG. 6B.

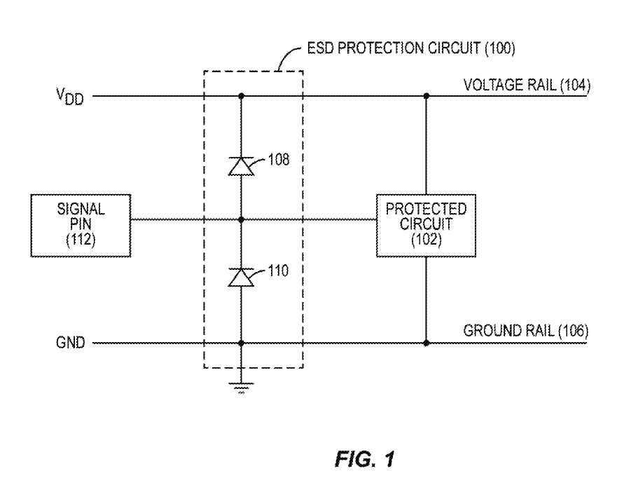

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include forming a self-aligned single diffusion break (SDB) isolation structure in a gate region of a diode for reduced capacitance, resistance, and/or area. In one aspect, a diode is provided that includes a semiconductor substrate having a well region, and P-type material doped (P-doped) and N-type material doped (N-doped) diffusion regions formed in the well region of the semiconductor substrate. A self-aligned SDB isolation structure is formed in and self-aligned with a gate region between the P-doped and N-doped diffusion regions. The self-aligned SDB isolation structure electrically isolates the P-doped and N-doped diffusion regions such that parasitic capacitance between the P-doped and N-doped diffusion regions and the self-aligned SDB isolation structure in the gate region is reduced or avoided. Forming the self-aligned SDB isolation structure in the gate region reduces the parasitic capacitance of the diode as compared to diodes that include conductive gate structures in the gate region. Additionally, having the self-aligned SDB isolation structure self-aligned with the gate region of the diode allows the self-aligned SDB isolation structure to be formed with a width corresponding to a width of the gate region to reduce the length of a discharge path, and thus the area, of the diode as compared to conventional diodes. A shorter discharge path reduces an on-state resistance of the diode, which increases current density. Further, as another example, the self-aligned SDB isolation structure can be formed without new fabrication masks in addition to masks used in conventional SDB processes, such that the diode can achieve a reduced capacitance, resistance, and/or area without increased manufacturing costs.

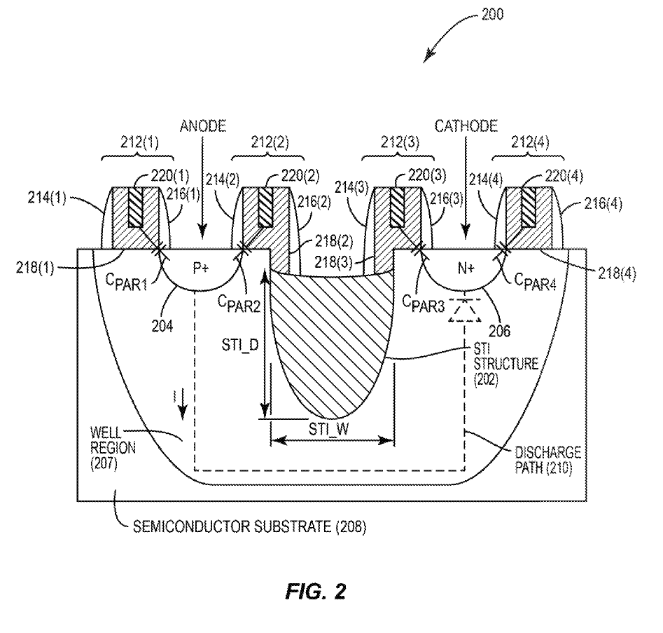

Before addressing exemplary aspects of the present disclosure, details of conventional diodes are first described. In this regard, FIG. 2 illustrates a cross-sectional view of an exemplary conventional diode 200 having a shallow trench isolation (STI) structure 202 separating a P-type material doped (P-doped) diffusion region 204 (P+) and an N-type material doped (N-doped) diffusion region 206 (N+). The P-doped diffusion region 204 corresponds to an anode (ANODE) of the diode 200, while the N-doped diffusion region 206 corresponds to a cathode (CATHODE) of the diode 200. The STI structure 202 is formed in a well region 207 of a semiconductor substrate 208 between the P-doped diffusion region 204 and the N-doped diffusion region 206 using a conventional STI process. As a result, the STI structure 202 is formed having a particular width (STI_W) and depth (STI_D) corresponding to the conventional STI process. Further, because the STI structure 202 separates the P-doped diffusion region 204 and the N-doped diffusion region 206, current (I) traverses through the diode 200 via a discharge path 210 formed around the perimeter of the STI structure 202. In this manner, the distance of the discharge path 210 is dependent on the width (STI_W) and the depth (STI_D) of the STI structure 202.

With continuing reference to FIG. 2, in addition to the employing the STI structure 202, the diode 200 also includes gate structures 212(1)-212(4). Each gate structure 212(1)-212(4) is configured to function as a dummy gate, and thus, includes a corresponding first spacer 214(1)-214(4) and second spacer 216(1)-216(4) formed around a corresponding dielectric layer 218(1)-218(4) and conductive layer 220(1)-220(4). A corresponding parasitic capacitance C_{PAR1}, C_{PAR2} is formed between the corresponding conductive layer 220(1), 220(2) and the P-doped diffusion region 204 of each gate structure 212(1), 212(2). A corresponding parasitic capacitance C_{PAR3}, C_{PAR4} is formed between the corresponding conductive layer 220(3), 220(4) and the N-doped diffusion region 206 of each gate structure 212(3), 212(4) such that the parasitic capacitance C_{PAR3}, C_{PAR4} is formed adjacent to the STI structure 202. In particular, the conductive layers 220(1)-220(4) and the corresponding P-doped or N-doped diffusion regions 204, 206 serve as conducting plates while the corresponding dielectric layers 218(1)-218(4) serve as the insulator layers to form the corresponding parasitic capacitances C_{PAR1}-C_{PAR4}. The parasitic capacitances C_{PAR1}-C_{PAR4} contribute to a resistor-capacitor (RC) delay of circuits employing the diode 200. As such capacitances increase, so too does the RC delay, which reduces the frequency at which the corresponding circuit can operate. Higher capacitance also increases the impedance of the corresponding circuit. Increased impedance negatively affects input matching, and thus degrades the return/loss of signals input or output from the corresponding circuit at certain frequencies.

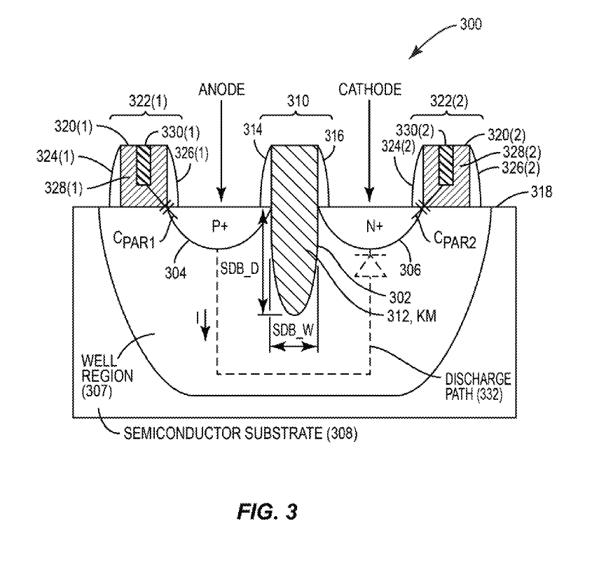

FIG. 3 illustrates a cross-sectional view of an exemplary diode 300 having a self-aligned SDB isolation structure 302 separating a P-type material doped (P-doped) diffusion region 304 and an N-type material doped (N-doped) diffusion region 306. As described below, the self-aligned SDB isolation structure 302 reduces the parasitic capacitance of the diode 300 as compared to the conventional diode 200 in FIG. 2. Additionally, the self-aligned SDB isolation structure 302 reduces an on-state resistance of the diode 300 as compared to the diode 200 in FIG. 2, which increases current density. The P-doped diffusion region 304 and N-doped diffusion region 306 are formed in a well region 307 of a semiconductor substrate 308. In this aspect, the well region 307 is doped with P-type impurities. However, other aspects can include the well region 307 doped with N-type impurities. Additionally, the P-doped diffusion region 304 is doped with p-type impurities (P+) and the N-doped diffusion region 306 is doped with n-type impurities (N+). In this aspect, the P-doped diffusion region 304 corresponds to an anode (ANODE) and the N-doped diffusion region 306 corresponds to a cathode (CATHODE) of the diode 300.

With continuing reference to FIG. 3, the self-aligned SDB isolation structure 302 is formed in and self-aligned with a gate region 310 disposed between the P-doped and N-doped diffusion regions 304, 306. In particular, as discussed in more detail below, the self-aligned SDB isolation structure 302 is considered self-aligned with the gate region 310, because the self-aligned SDB isolation structure 302 takes the place of a dummy gate removed from the gate region 310. The self-aligned SDB isolation structure 302 provides electrical isolation between the P-doped and N-doped diffusion regions 304, 306 (i.e., between the ANODE and CATHODE).

In this aspect, the self-aligned SDB isolation structure 302 includes an SDB trench 312 formed in the semiconductor substrate 308 using an SDB process. Such an SDB process can include etching a portion of the semiconductor substrate 308 to form a single break (e.g., the SDB trench 312) in the semiconductor substrate 308. For example, such etching may include employing anisotropic silicon etching, such as reactive ion etching, a polysilicon section (not shown) and the semiconductor substrate 308. In this manner, the self-aligned SDB isolation structure 302 is created by forming the SDB trench 312 between a first spacer 314 disposed adjacent to the gate region 310 and the P-doped diffusion region 304, and a second spacer 316 disposed adjacent to the gate region 310 and the N-doped diffusion region 306. As a non-limiting example, the first and second spacers 314, 316 can be formed from materials such as silicon nitride, silicon carbon nitride, or silicon carbon oxide nitride. Forming the SDB trench 312 between the first and second spacers 314, 316 in this manner results in the corresponding self-aligned SDB isolation structure 302 being self-aligned with the gate region 310. The SDB trench 312 is filled with a dielectric material (KM) such as, for example, silicon nitride plus silicon dioxide. The dielectric material (KM) extends above a top surface 318 of the semiconductor substrate 308. More specifically, the dielectric material (KM) extends so as to be planar with top surfaces 320(1), 320(2) of gate structures 322(1), 322(2) formed when manufacturing the diode 300.

With continuing reference to FIG. 3, including the dielectric material (KM) in the gate region 310 as opposed to including additional gate structures 322 reduces the parasitic capacitance of the diode 300 compared to the diode 200 in FIG. 2. In particular, the gate structures 322(1), 322(2) are similar to the gate structures 212(1)-212(4) in FIG. 2. Each gate structure 322(1), 322(2) is configured to function as a dummy gate, and thus includes a corresponding first spacer 324(1), 324(2) and second spacer 326(1), 326(2) on either side of a corresponding dielectric layer 328(1), 328(2) and conductive layer 330(1), 330(2). A corresponding parasitic capacitance C_{PAR1}, C_{PAR2} is formed corresponding to each gate structure 322(1), 322(2). In particular, the corresponding conductive layer 330(1), 330(2) and the P-doped and N-doped diffusion regions 304, 306 serve as conducting plates while the dielectric layers 328(1), 328(2) serve as insulator layers to form the corresponding parasitic capacitances C_{PAR1}, C_{PAR2}. However, unlike the STI process used in relation to the diode 200 in FIG. 2, the SDB process does not form gate structures 322 corresponding to the self-aligned SDB isolation structure 302. Instead, the gate region 310 includes the SDB trench 312 filled with the non-conductive dielectric material (KM) in place of another gate structure 322 (e.g., in place of another dummy gate).

With continuing reference to FIG. 3, by not including additional gate structures 322 in the gate region 310, parasitic capacitance corresponding to a gate structure 322 formed in the gate region 310 is reduced or avoided. More specifically, parasitic capacitance is reduced or avoided between the self-aligned SDB isolation structure 302 and the P-doped and N-doped diffusion regions 304, 306. Thus, the diode 300 has a parasitic capacitance that includes parasitic capacitances C_{PAR1}, C_{PAR2}, which is less than a parasitic capacitance of the diode 200 in FIG. 2 that includes parasitic capacitances C_{PAR1}-C_{PAR4.} In this manner, employing the self-aligned SDB isolation structure 302 allows the diode 300 to have a reduced capacitance compared to the conventional diode 200 in FIG. 2.

With continuing reference to FIG. 3, being self-aligned with the gate region 310 results in the SDB trench 312 having a width (SDB_W) corresponding to a width of the gate region 310. In this manner, the width (SDB_W) of the self-aligned SDB isolation structure 302 corresponds to the gate length of the technology used to fabricate the diode 300, and thus, the width (SDB_W) decreases proportionally as technology size decreases. As a non-limiting example, the width of the SDB trench 312 can be between approximately 18 nanometers (nm) and 22 nm when manufacturing the diode 300 in 10 nm technology. However, manufacturing the diode 300 using a technology size less than 10 nm results in a proportionally smaller width (SDB_W). Additionally, a depth (SDB_D) of the SDB trench 312 formed with the SDB process can be between approximately 60 nm and 100 nm when manufacturing the diode 300 in 10 nm technology. Both the width (SDB_W) and the depth (SDB_D) formed using the SDB process are smaller than the width (STI_W) and the depth (STI_D) formed using the STI process referenced in FIG. 2. As a result, the length of a discharge path 332, which is formed around the perimeter of the self-aligned SDB isolation structure 302 and in which current (I) flows through the diode 300, is reduced as compared to the diode 200 in FIG. 2. The shorter discharge path 332 results in the diode 300 having a reduced area as compared to the diode 200 in FIG. 2. The shorter discharge path 332 also reduces an on-state resistance of the diode 300, which increases current density of the diode 300 without increasing area. Further, the self-aligned SDB isolation structure 302 can be formed without new masks in addition to those used in conventional SDB processes. Therefore, the diode 300 having the self-aligned SDB isolation structure 302 achieves a reduced capacitance, resistance, and area over the conventional diode 200 in FIG. 2 without increased manufacturing costs.

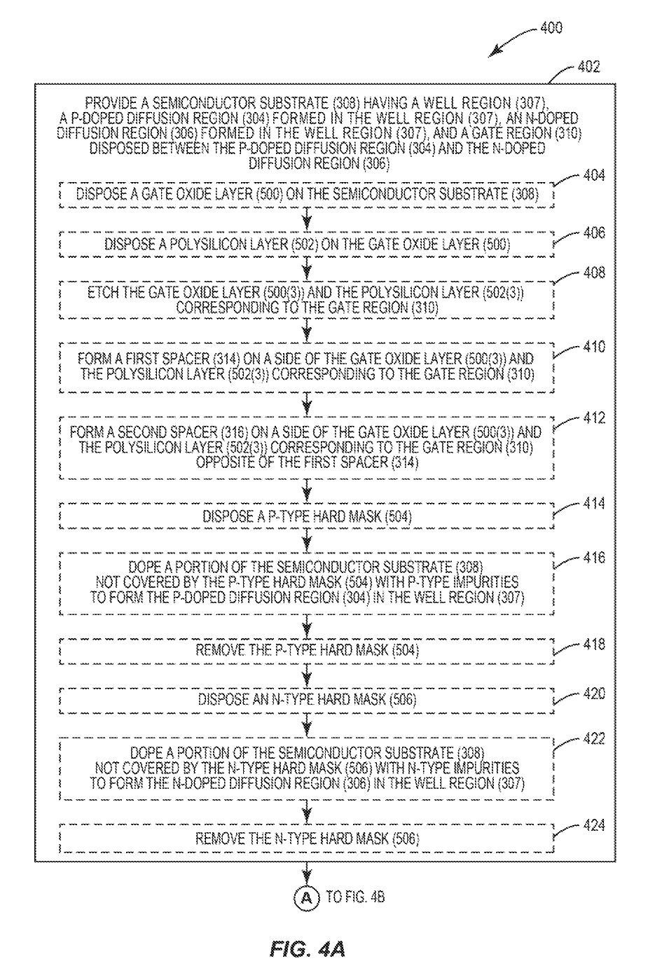

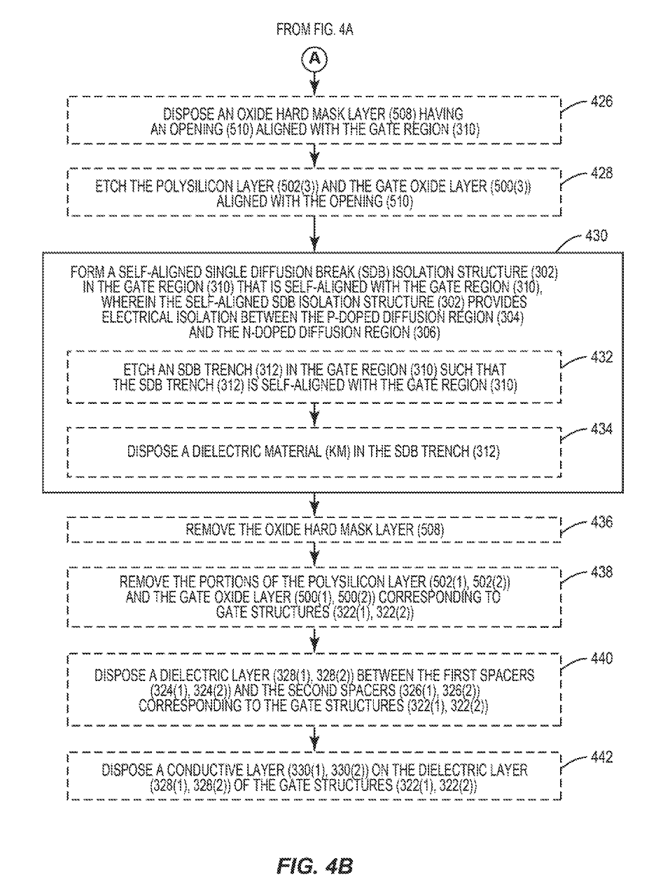

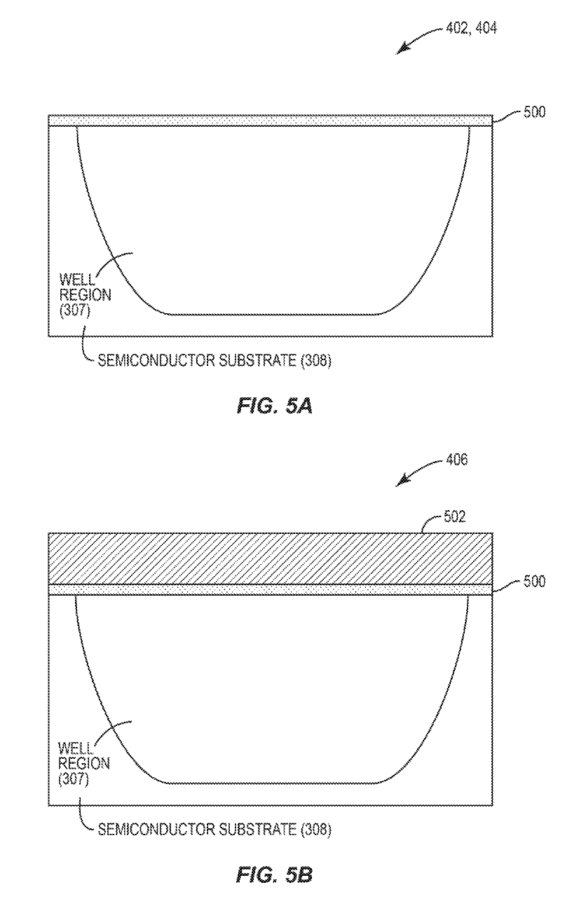

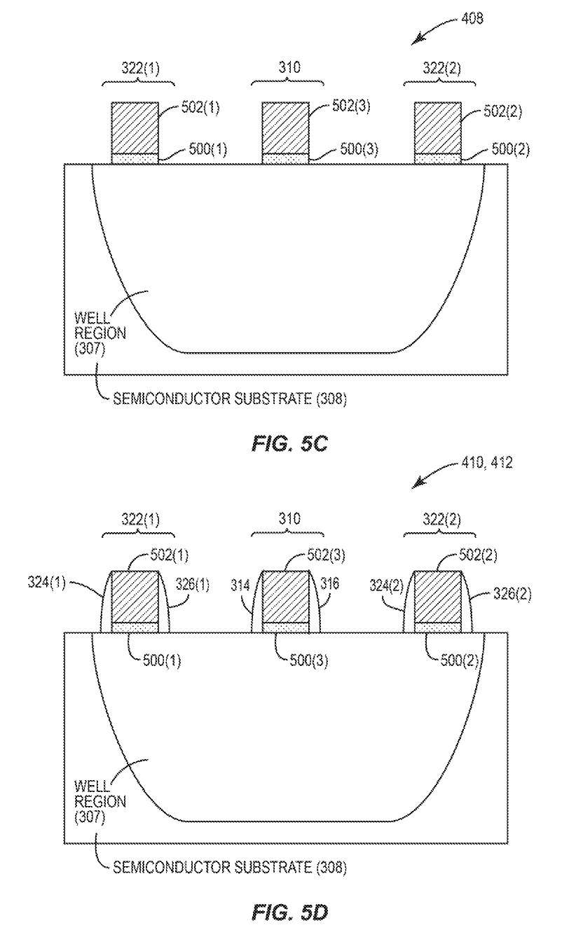

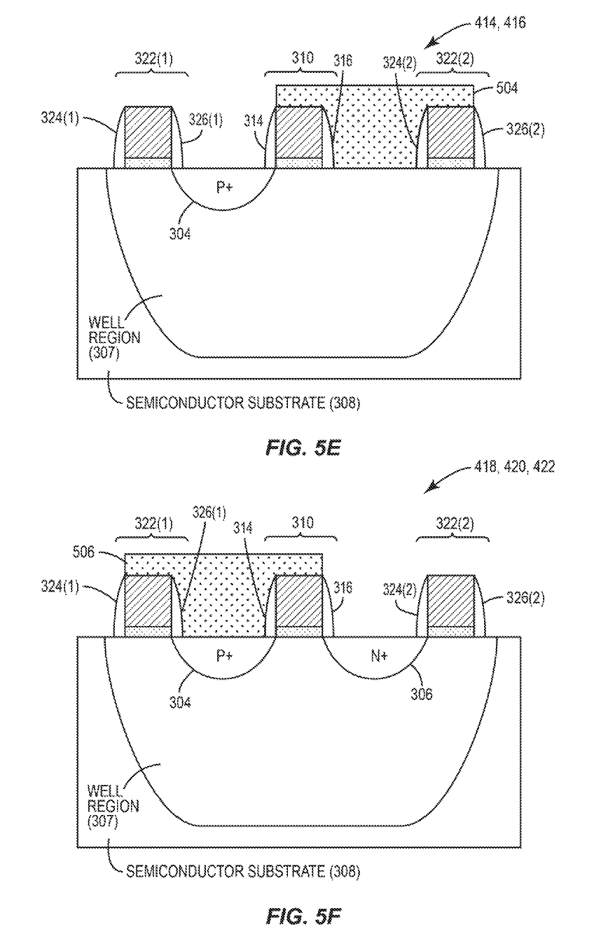

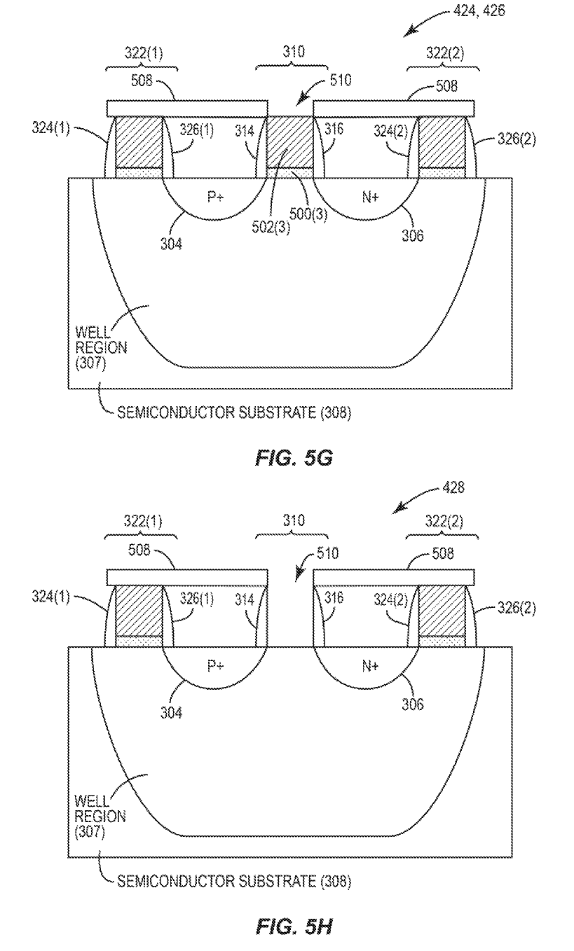

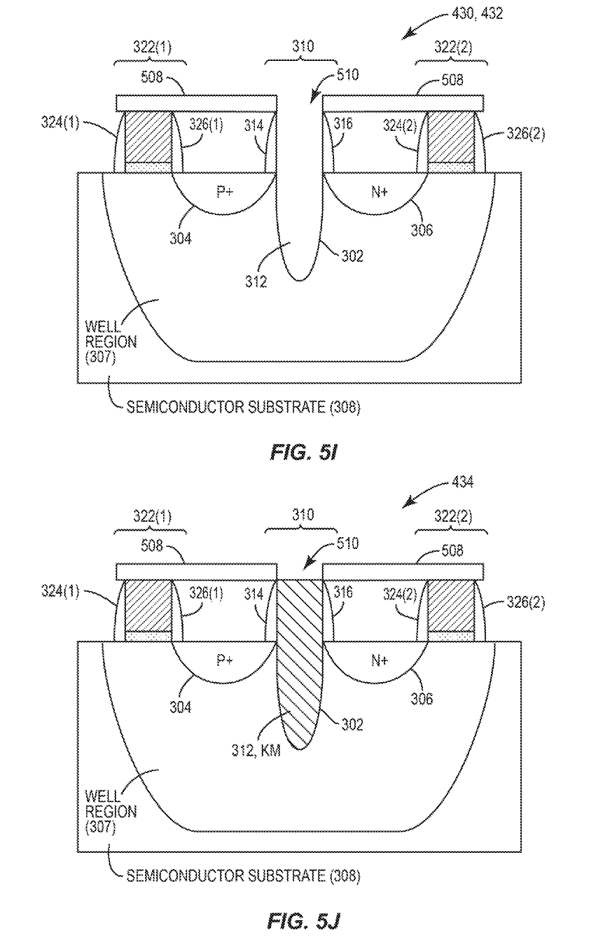

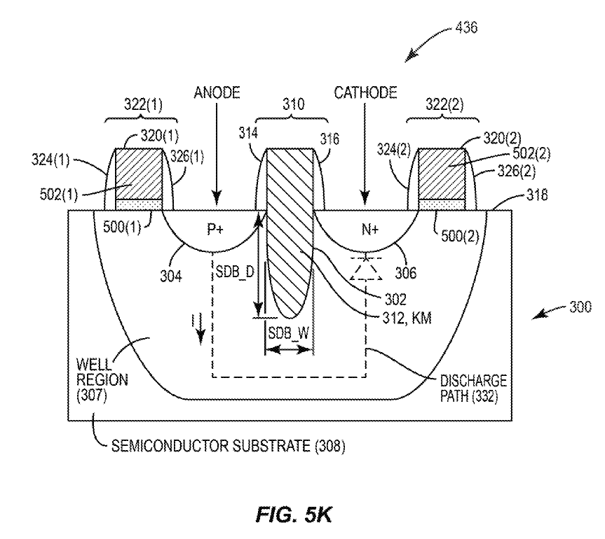

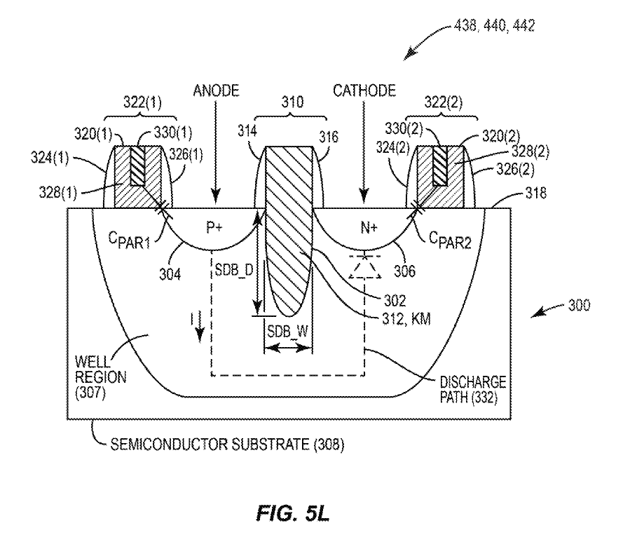

FIGS. 4A-4B illustrate an exemplary fabrication process 400 employed to fabricate the diode 300 in FIG. 3. Further, FIGS. 5A-5L provide cross-sectional diagrams illustrating the diode 300 during the steps of the fabrication process 400. The cross-sectional diagrams illustrating the diode 300 in FIGS. 5A-5L will be discussed in conjunction with the discussion of the exemplary fabrication steps in the fabrication process 400 in FIGS. 4A-4B.

In this regard, the fabrication process 400 beginning in FIG. 4A includes providing the semiconductor substrate 308 having the well region 307, the P-doped diffusion region 304 formed in the well region 307, the N-doped diffusion region 306 formed in the well region 307, and the gate region 310 disposed between the P-doped diffusion region 304 and the N-doped diffusion region 306 (block 402 and FIGS. 5A-5F). In this aspect, the fabrication process 400 can include multiple steps to provide the semiconductor substrate 308 in block 402. For example, block 402 can include disposing a gate oxide layer 500 on the semiconductor substrate 308 (block 404 and FIG. 5A). Block 402 can also include disposing a polysilicon layer 502 on the gate oxide layer 500 (block 406 and FIG. 5B). Further, block 402 can include etching the gate oxide layer 500(3) and the polysilicon layer 502(3) corresponding to the gate region 310 (block 408 and FIG. 5C). To include the gate structures 322(1), 322(2) in the diode 300 in FIG. 3, the gate oxide layer 500 and the polysilicon layer 502 can also be etched such that the gate oxide layer 500(1), 500(2) and the polysilicon layer 502(1), 502(2) reside on either side of the P-doped and N-doped diffusion regions 304, 306 opposite the gate region 310, as illustrated in FIG. 5C. Block 402 can further include forming the first spacer 314 on a side of the gate oxide layer 500(3) and the polysilicon layer 502(3) corresponding to the gate region 310 (block 410 and FIG. 5D). Block 402 can also include forming the second spacer 316 on a side of the gate oxide layer 500(3) and the polysilicon layer 502(3) corresponding to the gate region 310 opposite of the first spacer 314 (block 412 and FIG. 5D). Additionally, including the gate structures 322(1), 322(2) results in the corresponding first spacers 324(1), 324(2) and second spacers 326(1), 326(2) also being formed. In this manner, as illustrated in FIG. 5D, the gate structures 322(1), 322(2) are formed on either side of the gate region 310.

With continuing reference to FIG. 4A, block 402 can also include disposing a p-type hard mask 504 (block 414 and FIG. 5E), and doping a portion of the semiconductor substrate 308 not covered by the p-type hard mask 504 with p-type impurities to form the P-doped diffusion region 304 in the well region 307 (block 416 and FIG. 5E). Further, block 402 can include removing the p-type hard mask 504 (block 418 and FIG. 5F). Block 402 can also include disposing an n-type hard mask 506 (block 420 and FIG. 5F), and doping a portion of the semiconductor substrate 308 not covered by the n-type hard mask 506 with n-type impurities to form the N-doped diffusion region 306 in the well region 307 (block 422 and FIG. 5F). Additionally, block 402 can include removing the n-type hard mask 506 (block 424 and FIG. 5G).

With reference to FIG. 4B, in response to providing the semiconductor substrate 308 according to block 402 and/or the steps described therein, the fabrication process 400 can also include disposing an oxide hard mask layer 508 having an opening 510 aligned with the gate region 310 (block 426 and FIG. 5G). The fabrication process 400 can further include etching the polysilicon layer 502(3) and the gate oxide layer 500(3) aligned with the opening 510 (block 428 and FIG. 5H).

With continuing reference to FIG. 4B, the fabrication process 400 includes forming the self-aligned SDB isolation structure 302 in the gate region 310 (block 430 and FIGS. 5I, 5J). As previously described, the self-aligned SDB isolation structure 302 is self-aligned with the gate region 310, and provides electrical isolation between the P-doped diffusion region 304 and the N-doped diffusion region 306. In this aspect, forming the self-aligned SDB isolation structure 302 in block 430 can include multiple steps. For example, forming the self-aligned SDB isolation structure 302 in block 430 includes etching the SDB trench 312 in the gate region 310 such that the SDB trench 312 is self-aligned with the gate region 310 (block 432 and FIG. 51). As previously described, the semiconductor substrate 308 can be etched to form the SDB trench 312 to a depth between approximately 60 nm and 100 nm, for example. Additionally, because forming the SDB trench 312 in this manner includes employing the SDB process, the SDB trench 312 is self-aligned with the gate region 310, as previously described. Forming the self-aligned SDB isolation structure 302 in block 430 can also include disposing the dielectric material (KM) in the SDB trench 312 (block 434 and FIG. 5J).

With continuing reference to FIG. 4B, following formation of the self-aligned SDB isolation structure 302 in block 430, the fabrication process 400 can include removing the oxide hard mask layer 508 (block 436 and FIG. 5K). The oxide hard mask layer 508 can be removed in a variety of ways, such as, but not limited to, planarizing the oxide hard mask layer 508 using chemical mechanical polishing (CMP). Additionally, the fabrication process 400 can include removing the portions of the polysilicon layer 502(1), 502(2) and the gate oxide layer 500(1), 500(2) corresponding to the gate structures 322(1), 322(2) (block 438 and FIG. 5L). The fabrication process 400 can also include disposing the dielectric layer 328(1), 328(2) between the first spacers 324(1), 324(2) and the second spacers 326(1), 326(2) corresponding to the gate structures 322(1), 322(2) (block 440 and FIG. 5L). Further, the fabrication process 400 can include disposing the conductive layer 330(1), 330(2) on the dielectric layer 328(1), 328(2) of the gate structures 322(1), 322(2) (block 442 and FIG. 5L).

As previously described, the gate structures 322(1), 322(2) form the corresponding parasitic capacitances C_{PAR1}, C_{PAR2}. However, as noted earlier, because the self-aligned SDB isolation structure 302 is non-conductive, parasitic capacitance is reduced or avoided between the self-aligned SDB isolation structure 302 and the semiconductor substrate 308. Further, the shorter discharge path 332 described above reduces the area and on-state resistance of the diode 300 compared to the diode 200 in FIG. 2. In this manner, manufacturing the diode 300 using the fabrication process 400 achieves a reduced capacitance, resistance, and/or area of the diode 300. Additionally, because forming the self-aligned SDB isolation structure 302 does not involve new fabrication masks beyond what is used in conventional SDB processes, the diode 300 can be manufactured without increased manufacturing costs.

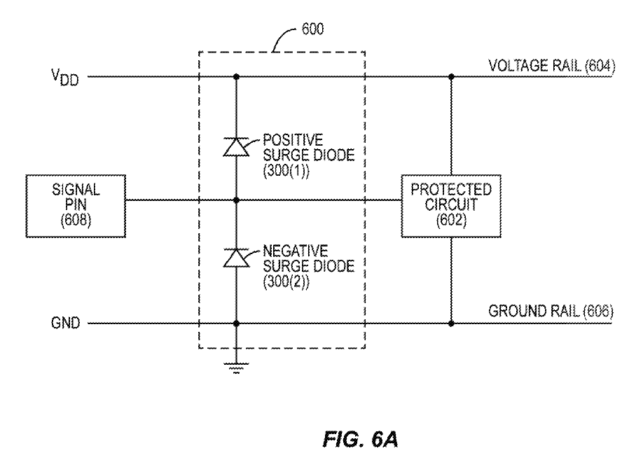

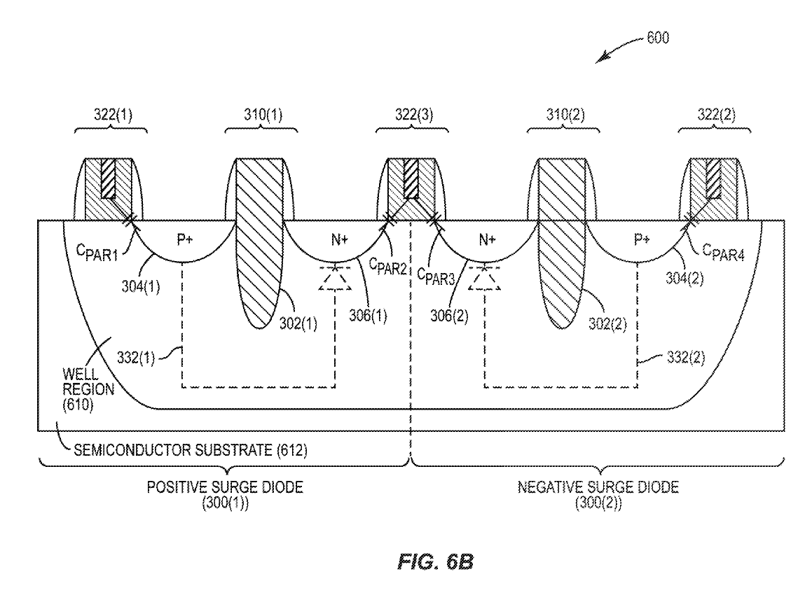

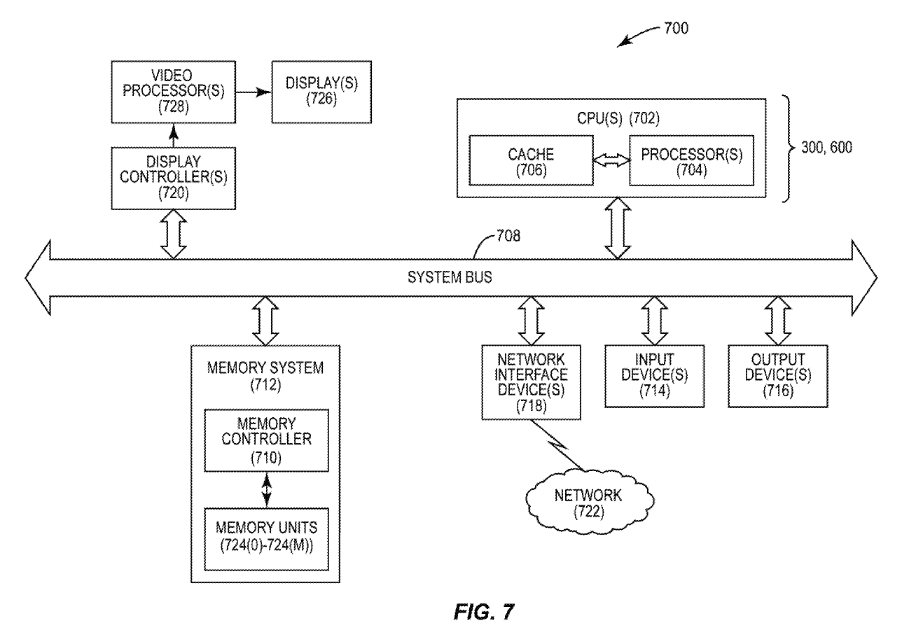

Due to the reduced capacitance, resistance, and/or area of the diode 300 employing the self-aligned SDB isolation structure 302, using such diodes can increase the performance of corresponding circuits. As a non-limiting example, FIG. 6A illustrates a circuit diagram of an exemplary ESD protection circuit 600 configured to provide ESD protection to a protected circuit 602. The ESD protection circuit 600 employs two instances of the diode 300 in FIG. 3, a positive surge diode 300(1) and a negative surge diode 300(2). The ESD protection circuit 600 is coupled between a voltage rail 604 and a ground rail 606 so as to protect the protected circuit 602 from both positive and negative ESD surges. A signal pin 608 is configured to convey a voltage signal to the protected circuit 602. In this manner, in response to positive ESD surges on the signal pin 608, the positive surge diode 300(1) is configured to enter a forward-biased mode and clamp voltage on the signal pin 608 to one diode drop above the voltage rail 604. Energy from such a positive ESD surge is conducted through the positive surge diode 300(1) in the forward-biased mode and dispersed onto the voltage rail 604. In contrast, in response to negative ESD surges on the signal pin 608, the negative surge diode 300(2) is configured to enter a forward-biased mode so as to provide a low-impedance path relative to the protected circuit 602. Energy from the negative ESD surge dissipates onto the ground rail 606.

FIG. 6B illustrates a cross-sectional diagram of the ESD protection circuit 600 in FIG. 6A. The positive surge diode 300(1) and the negative surge diode 300(2) each include certain common components with the diode 300 in FIG. 3, as shown by similar element numbers between FIGS. 3 and 6B, and thus will not be re-described herein. The positive surge diode 300(1) includes a self-aligned SDB isolation structure 302(1) that is self-aligned with a gate region 310(1) disposed between a P-doped diffusion region 304(1) and an N-doped diffusion region 306(1) formed in a well region 610 of a semiconductor substrate 612. Similarly, the negative surge diode 300(2) includes a self-aligned SDB isolation structure 302(2) that is self-aligned with a gate region 310(2) disposed between a P-doped diffusion region 304(2) and an N-doped diffusion region 306(2) formed in the well region 610. Additionally, rather than the positive and negative surge diodes 300(1), 300(2) each including two separate gate structures 322 similar to the diode 300 in FIG. 3, the positive surge diode 300(1) includes a gate structure 322(1) and the negative surge diode 300(2) includes a gate structure 322(2). A gate structure 322(3) is shared between the positive and negative surge diodes 300(1), 300(2).

With continuing reference to FIG. 6B, parasitic capacitances C_{PAR1}-C_{PAR4} are formed between the gate structures 322(1)-322(3) and the P-doped diffusion regions 304(1), 304(2) and the N-doped diffusion regions 306(1), 306(2), respectively. However, parasitic capacitance is reduced or avoided corresponding to the self-aligned SDB isolation structures 302(1), 302(2). Therefore, the positive and negative surge diodes 300(1), 300(2) have a combined parasitic capacitance that includes the parasitic capacitances C_{PAR1}-C_{PAR4}. Thus, the positive and negative surge diodes 300(1), 300(2) cause the ESD protection circuit 600 to have a reduced capacitance compared to similar circuits that employ the conventional diode 200 in FIG. 2. Such a reduced capacitance reduces a resistor-capacitor (RC) delay of the ESD protection circuit 600, thereby increasing the frequency at which the protected circuit 602 can operate. Reduced capacitance also reduces the impedance of the protected circuit 602, which improves input matching and the return/loss of signals input or output from the protected circuit 602. Additionally, shorter discharge paths 332(1), 332(2) reduce an on-state resistance of the positive and negative surge diodes 300(1), 300(2), respectively. Reduction of the on-state resistance increases current density of the positive and negative surge diodes 300(1), 300(2) without increasing area. A higher current density enables a faster discharge of ESD surges, which improves performance of the ESD protection circuit 600. Further, the self-aligned SDB isolation structures 302(1), 302(2) can be formed without new fabrication masks in addition to what is used in conventional SDB processes. Therefore, employing the positive and negative surge diodes 300(1), 300(2) improves the performance of integrated circuits (ICs) employing the ESD protection circuit 600 without an increase in manufacturing costs.

The elements described herein are sometimes referred to as means for achieving a particular property. In this regard, the semiconductor substrate 308 is sometimes referred to herein as “a means for providing a semiconductor substrate comprising a well region.” The P-doped diffusion region 304 is sometimes referred to herein as “a means for providing a P-type material doped (P-doped) diffusion region formed in the well region.” The N-doped diffusion region 306 is sometimes referred to herein as “a means for providing an N-type material doped (N-doped) diffusion region formed in the well region.” The gate region 310 is sometimes referred to herein as “a means for disposing a gate region between the P-doped diffusion region and the N-doped diffusion region.” The self-aligned SDB isolation structure 302 is sometimes referred to herein as “a means for forming a self-aligned SDB isolation structure in the gate region and self-aligned with the gate region.”

Forming a self-aligned SDB isolation structure in a gate region of a diode for reduced capacitance, resistance, and/or area according to aspects disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a smart phone, a tablet, a phablet, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, and an automobile.

In this regard, FIG. 7 illustrates an example of a processor-based system 700 that includes elements that can employ the diode 300 in FIG. 3 and the ESD protection circuit 600 in FIG. 6B. In this example, the processor-based system 700 includes one or more central processing units (CPUs) 702, each including one or more processors 704. The CPU(s) 702 may have cache memory 706 coupled to the processor(s) 704 for rapid access to temporarily stored data. The CPU(s) 702 is coupled to a system bus 708 and can intercouple master and slave devices included in the processor-based system 700. As is well known, the CPU(s) 702 communicates with these other devices by exchanging address, control, and data information over the system bus 708. For example, the CPU(s) 702 can communicate bus transaction requests to a memory controller 710 as an example of a slave device. Although not illustrated in FIG. 7, multiple system buses 708 could be provided, wherein each system bus 708 constitutes a different fabric.

Other master and slave devices can be connected to the system bus 708. As illustrated in FIG. 7, these devices can include a memory system 712, one or more input devices 714, one or more output devices 716, one or more network interface devices 718, and one or more display controllers 720, as examples. The input device(s) 714 can include any type of input device, including, but not limited to, input keys, switches, voice processors, etc. The output device(s) 716 can include any type of output device, including, but not limited to, audio, video, other visual indicators, etc. The network interface device(s) 718 can be any device configured to allow exchange of data to and from a network 722. The network 722 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 718 can be configured to support any type of communications protocol desired. The memory system 712 can include one or more memory units 724(0)-724(M).

The CPU(s) 702 may also be configured to access the display controller(s) 720 over the system bus 708 to control information sent to one or more displays 726. The display controller(s) 720 sends information to the display(s) 726 to be displayed via one or more video processors 728, which process the information to be displayed into a format suitable for the display(s) 726. The display(s) 726 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. A diode, comprising:
a semiconductor substrate comprising a well region;
a P-type material doped (P-doped) diffusion region formed in the well region;
an N-type material doped (N-doped) diffusion region formed in the well region;
a gate region disposed between the P-doped diffusion region and the N-doped diffusion region; and
a self-aligned single diffusion break (SDB) isolation structure formed in the gate region and self-aligned with the gate region, the self-aligned SDB isolation structure providing electrical isolation between the P-doped diffusion region and the N-doped diffusion region.

2. The diode of claim 1, wherein the self-aligned SDB isolation structure comprises an SDB trench filled with a dielectric material.

3. The diode of claim 2, further comprising:
a first spacer disposed adjacent to the gate region and the P-doped diffusion region; and
a second spacer disposed adjacent to the gate region and the N-doped diffusion region,
wherein the SDB trench of the self-aligned SDB isolation structure is formed between the first spacer and the second spacer.

4. The diode of claim 3, wherein the dielectric material of the self-aligned SDB isolation structure extends above a top surface of the semiconductor substrate.

5. The diode of claim 4, further comprising a gate structure, wherein a top surface of the dielectric material of the self-aligned SDB isolation structure is planar with a top surface of the gate structure.

6. The diode of claim 2, wherein the SDB trench has a width between approximately 18 nanometers (nm) and 22 nm.

7. The diode of claim 2, wherein the SDB trench has a depth between approximately 60 nanometers (nm) and 100 nm.

8. The diode of claim 1 integrated into an integrated circuit (IC).

9. The diode of claim 1 integrated into a device selected from the group consisting of: a set top box; an entertainment unit; a navigation device; a communications device; a fixed location data unit; a mobile location data unit; a mobile phone; a cellular phone; a smart phone; a tablet; a phablet; a computer; a portable computer; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; and an automobile.

10. A method for manufacturing a diode, comprising:
providing a semiconductor substrate comprising a well region, a P-type material doped (P-doped) diffusion region formed in the well region, an N-type material doped (N-doped) diffusion region formed in the well region, and a gate region disposed between the P-doped diffusion region and the N-doped diffusion region; and
forming a self-aligned single diffusion break (SDB) isolation structure in the gate region that is self-aligned with the gate region, wherein the self-aligned SDB isolation structure provides electrical isolation between the P-doped diffusion region and the N-doped diffusion region.

11. The method of claim 10, further comprising:
disposing an oxide hard mask layer comprising an opening aligned with the gate region;
etching a polysilicon layer and a gate oxide layer aligned with the opening; and
removing the oxide hard mask layer.

12. The method of claim 10, wherein forming the self-aligned SDB isolation structure comprises:
etching an SDB trench in the gate region such that the SDB trench is self-aligned with the gate region; and
disposing a dielectric material in the SDB trench.

13. The method of claim 12, wherein disposing the dielectric material comprises disposing the dielectric material to extend above a top surface of the semiconductor substrate.

14. The method of claim 13, further comprising:
forming a gate structure outside of the gate region; and
wherein disposing the dielectric material further comprises disposing the dielectric material to be planar with a top surface of the gate structure.

15. The method of claim 12, wherein etching the SDB trench in the gate region comprises etching the semiconductor substrate to a depth between approximately 18 nanometers (nm) and 22 nm to form the SDB trench.

16. The method of claim 10, wherein providing the semiconductor substrate comprises:
disposing a gate oxide layer on the semiconductor substrate;
disposing a polysilicon layer on the gate oxide layer;
etching the gate oxide layer and the polysilicon layer corresponding to the gate region;
forming a first spacer on a side of the gate oxide layer and the polysilicon layer corresponding to the gate region;
forming a second spacer on a side of the gate oxide layer and the polysilicon layer corresponding to the gate region opposite of the first spacer;
disposing a p-type hard mask;
doping a portion of the semiconductor substrate not covered by the p-type hard mask with p-type impurities to form the P-doped diffusion region in the well region;
removing the p-type hard mask;
disposing an n-type hard mask;
doping a portion of the semiconductor substrate not covered by the n-type hard mask with n-type impurities to form the N-doped diffusion region in the well region; and
removing the n-type hard mask.

17. The method of claim 10, further comprising:
removing a polysilicon layer and a gate oxide layer corresponding to a plurality of gate structures;
disposing a dielectric layer between first spacers and second spacers corresponding to the plurality of gate structures; and
disposing a conductive layer on the dielectric layer of the plurality of gate structures.

18. An electro-static discharge (ESD) protection circuit, comprising:
a signal pin configured to convey a voltage signal to a protected circuit;
a positive surge diode coupled to the signal pin and a voltage rail, comprising:
a semiconductor substrate comprising a well region;
a P-type material doped (P-doped) diffusion region formed in the well region;
an N-type material doped (N-doped) diffusion region formed in the well region;
a gate region disposed between the P-doped diffusion region and the N-doped diffusion region; and
a self-aligned single diffusion break (SDB) isolation structure formed in the gate region and self-aligned with the gate region, the self-aligned SDB isolation structure providing electrical isolation between the P-doped diffusion region and the N-doped diffusion region; and
a negative surge diode coupled to the signal pin and a ground rail, comprising:
the semiconductor substrate;
a P-doped diffusion region formed in the well region;
an N-doped diffusion region formed in the well region;
a gate region disposed between the P-doped diffusion region and the N-doped diffusion region; and
a self-aligned SDB isolation structure formed in the gate region and self-aligned with the gate region, the self-aligned SDB isolation structure providing electrical isolation between the P-doped diffusion region and the N-doped diffusion region.

19. The ESD protection circuit of claim 18, wherein:
the positive surge diode is configured to enter a forward-biased mode in response to a positive electro-static discharge surge; and
the negative surge diode is configured to enter a forward-biased mode in response to a negative electro-static discharge surge.

20. The ESD protection circuit of claim 18, wherein:
the self-aligned SDB isolation structure of the positive surge diode comprises an SDB trench filled with a dielectric material; and
the self-aligned SDB isolation structure of the negative surge diode comprises an SDB trench filled with a dielectric material.

21. The ESD protection circuit of claim 20, wherein:
the positive surge diode further comprises:
a first spacer disposed adjacent to the gate region and the P-doped diffusion region of the positive surge diode; and
a second spacer disposed adjacent to the gate region and the N-doped diffusion region of the positive surge diode,
wherein the SDB trench of the self-aligned SDB isolation structure of the positive surge diode is formed between the first spacer and the second spacer of the positive surge diode; and
the negative surge diode further comprises:
a first spacer disposed adjacent to the gate region and the P-doped diffusion region of the negative surge diode; and
a second spacer disposed adjacent to the gate region and the N-doped diffusion region of the negative surge diode,
wherein the SDB trench of the self-aligned SDB isolation structure of the negative surge diode is formed between the first spacer and the second spacer of the negative surge diode.

22. The ESD protection circuit of claim 21, wherein:
the dielectric material of the self-aligned SDB isolation structure of the positive surge diode extends above a top surface of the semiconductor substrate; and
the dielectric material of the self-aligned SDB isolation structure of the negative surge diode extends above the top surface of the semiconductor substrate.

23. The ESD protection circuit of claim 22, further comprising:
a gate structure;
wherein a top surface of the dielectric material of the self-aligned SDB isolation structure of the positive surge diode is planar with a top surface of the gate structure; and
wherein a top surface of the dielectric material of the self-aligned SDB isolation structure of the negative surge diode is planar with the top surface of the gate structure.

24. The ESD protection circuit of claim 20, wherein:
the SDB trench of the positive surge diode has a width between approximately 18 nanometers (nm) and 22 nm; and
the SDB trench of the negative surge diode has a width between approximately 18 nm and 22 nm.

25. The ESD protection circuit of claim 20, wherein:
the SDB trench of the positive surge diode has a depth between approximately 60 nanometers (nm) and 100 nm; and
the SDB trench of the negative surge diode has a depth between approximately 60 nm and 100 nm.

26. The ESD protection circuit of claim 18 integrated into an integrated circuit (IC).

27. The ESD protection circuit of claim 18 integrated into a device selected from the group consisting of: a set top box; an entertainment unit; a navigation device; a communications device; a fixed location data unit; a mobile location data unit; a mobile phone; a cellular phone; a smart phone; a tablet; a phablet; a computer; a portable computer; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; and an automobile.

28. A diode, comprising:
a means for providing a semiconductor substrate comprising a well region;
a means for providing a P-type material doped (P-doped) diffusion region formed in the well region;
a means for providing an N-type material doped (N-doped) diffusion region formed in the well region;
a means for disposing a gate region between the P-doped diffusion region and the N-doped diffusion region; and
a means for forming a self-aligned single diffusion break (SDB) isolation structure in the gate region and self-aligned with the gate region, the self-aligned SDB isolation structure providing electrical isolation between the P-doped diffusion region and the N-doped diffusion region.
